(19) United States
(12) Patent Application Publication
(10) Pub. No.: US 2009/0308640 A1
(43) Pub. Date: Dec. 17, 2009

(54) Wafer level package and method of manufacturing the same

(75) Inventors: Won Kyu Jeung, Seoul (KR); Yi Sung, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/232,253

(22) Filed: Sep. 12, 2008

(30) Foreign Application Priority Data
Jun. 16, 2008 (KR) 10-2008-0056323

(51) Int. Cl. H05K 1/03; H05K 3/36

(52) U.S. Cl. 174/255; 29/830

(57) ABSTRACT

Provided is a wafer level package including a first substrate that has circuit patterns provided on the top surface thereof and first vias formed therein, the first vias being electrically connected to the circuit patterns; and a second substrate that is bonded to the bottom surface of the first substrate through anodic bonding and has second vias formed therein.

### CROSS-REFERENCE TO RELATED APPLICATIONS

This application claims the benefit of Korean Patent Application No. 10-2008-0056323 filed with the Korea Intellectual Property Office on Jun. 16, 2008, the disclosure of which is incorporated herein by reference.

### BACKGROUND OF THE INVENTION

1. Field of the Invention

The present invention relates to a wafer level package and a method of manufacturing the same, in which substrates are bonded to each other through anodic bonding.

2. Description of the Related Art

Recently, an interest in packaging techniques which satisfy a demand for the miniaturization of semiconductor devices has been increasing. Among the packaging techniques, a wafer-level packaging technique is where components are assembled on a wafer which is not separated into chips, different from an existing packaging technique in which chips cut from a wafer are packaged one by one.

Specifically, a series of processes including circuit design, wafer processing, assembling, and inspection are performed so as to manufacture one semiconductor element. In the assembling process including a wiring connection process and a packaging process, chips are cut from a processed wafer and are then attached to small circuit boards, respectively. Then, after wring lines are connected, the circuit boards are covered by plastic packages.

In the wafer level package technique, an insulating material is applied on chips of a wafer, instead of plastic which has been used as a package material. Then, after wiring lines are connected, an insulating material is again applied. That is, the package process is performed through such a simple procedure.

When such a package technique is applied, the semiconductor assembling process is simplified. Further, plastic, circuit boards, and wires, which have been used in a conventional semiconductor assembling process, do not need to be used, which makes it possible to significantly reduce the manufacturing cost. Further, it is possible to manufacture a package having the same size as chips.

When such a wafer level package is manufactured, substrates may be bonded to each other through an adhesive layer such as epoxy resin. However, such an adhesive layer has low chemical resistance and poor optical characteristic. Further, components may be contaminated by the adhesive layer.

Further, the aging characteristic of the bonded portion is degraded, thereby accompanying the characteristic degradation of the bonded portion. Due to a difference in thermal expansion coefficient between the adhesive layer and the substrates, warpage of the wafer may occur, and there is a limit in managing thickness tolerance.

### SUMMARY OF THE INVENTION

An advantage of the present invention is that it provides a wafer level package and a method of manufacturing the same, in which as substrates are bonded to each other through anodic bonding, a separate adhesive material does not need to be used, thereby enhancing the reliability of the package.

Additional aspect and advantages of the present general inventive concept will be set forth in part in the description which follows and, in part, will be obvious from the description, or may be learned by practice of the general inventive concept.

According to an aspect of the invention, a wafer level package comprises a first substrate that has circuit patterns provided on the top surface thereof and first vias formed therein, the first vias being electrically connected to the circuit patterns; and a second substrate that is bonded to the bottom surface of the first substrate through anodic bonding and has second vias formed therein.

The first substrate may be formed of a material containing silicon or a material containing alkali metal. In this case, the material containing alkali metal may be glass.

When the first substrate is formed of a material containing silicon, the second substrate may be formed of a material containing alkali metal. Alternatively, when the first substrate is formed of a material containing alkali metal, the second substrate may be formed of a material containing silicon.

The wafer level package further comprises bonding pads that are provided between the first and second substrates so as to electrically connect the first vias to the second vias.

The wafer level package further comprises external connection portions that are provided on the bottom surface of the second substrate so as to be electrically connected to the second vias.

According to another aspect of the invention, a method of manufacturing a wafer level package comprises providing a first substrate which has circuit patterns provided on the top surface thereof, bonding pads provided on the bottom surface thereof, and first vias formed therein, the first vias electrically connecting the circuit patterns to the bonding pads; and bonding a second substrate to the bottom surface of the first substrate through anodic bonding, the second substrate having second vias formed therein, the second vias being electrically connected to the bonding pads.

The anodic bonding may be performed under a condition where the temperature is set to less than 200° C. and a voltage is set in the range of 800 to 2000V.

The method further comprises forming external connection portions on the bottom surface of the second substrate, the external connection portions being electrically connected to the second vias, after the bonding of the second substrate.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a wafer level package according to an embodiment of the invention; and

Referring to FIGS. 2 to 4, a method of manufacturing a wafer level package according to an embodiment of the invention will be described.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a wafer level package and a method of manufacturing the same according to the present invention will be described in detail with reference to the accompanying drawings.

Structure of Wafer Level Package

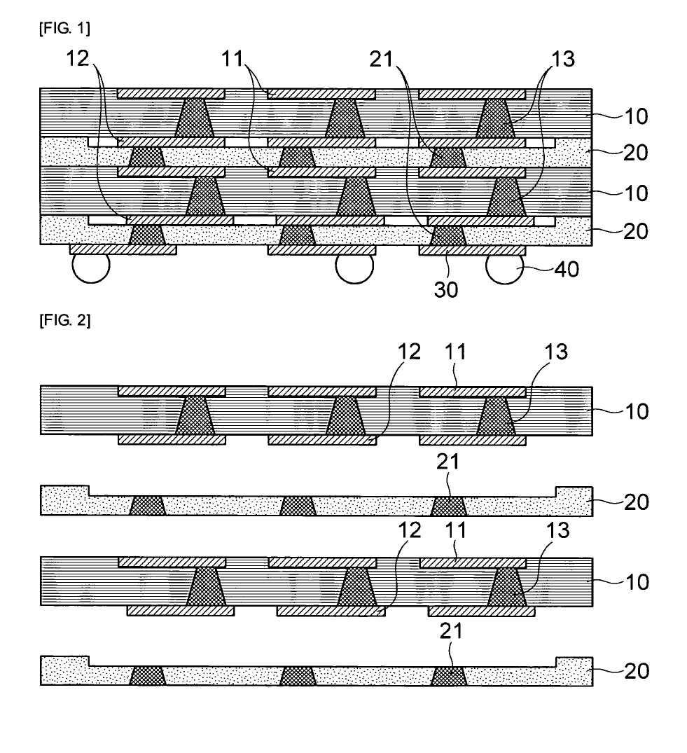

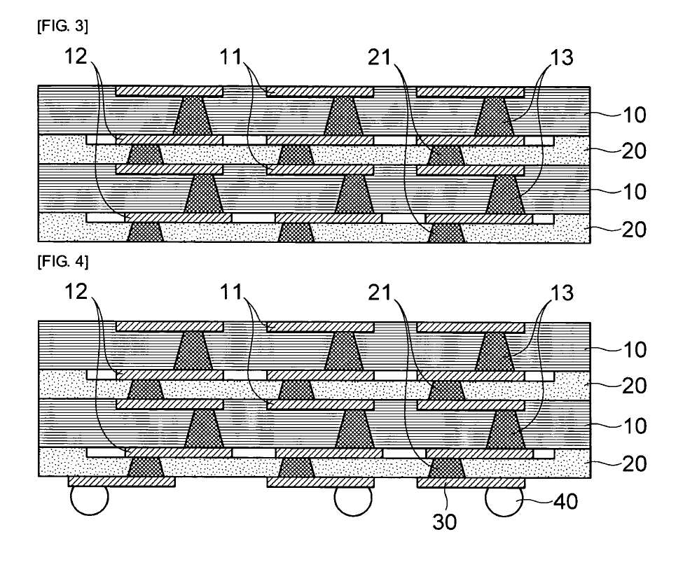

Referring to FIG. 1, a wafer level package according to an embodiment of the invention will be described.

FIG. 1 is a cross-sectional view of a wafer level package according to an embodiment of the invention.

As shown in FIG. 1, the wafer level package according to the embodiment of the invention includes a first substrate 10 having circuit patterns provided on the top surface thereof and a second substrate 20 bonded to the bottom surface of the first substrate 10 through anodic bonding.

The first substrate 10 may be formed of a material containing silicon (Si). Preferably, the first substrate 10 is formed of silicon. Alternatively, the first substrate 1 0 may be formed of a material containing alkali metal instead of the material containing silicon. As for the material containing alkali metal, glass or the like may be used.

When the first substrate 10 is formed of a material containing silicon, it is preferable that the second substrate 20 is formed of a material containing alkali metal, such as glass.

Alternately, when the first substrate 10 is formed of a material containing alkali metal, it is preferable that the second substrate 20 is formed of a material containing silicon.

The first substrate 10 has first vias 13 formed therein, the first vias 13 being electrically connected to the circuit patterns 11.

The second substrate 20 has second vias 21 formed therein, the second vias 21 passing through the second substrate 20.

The first and second vias 13 and 21 may be formed by the following process: via holes are formed in the first and second 10 and 20, respectively, through an etching or punching process, and are then filled with metal or conductive paste.

Between the first and second substrates 10 and 20, first bonding pads 12 are formed so as to electrically connect the first vias 13 of the first substrate 10 to the second vias 21 of the second substrate 20.

The wafer level package according to the embodiment of the invention may have a structure that the first and second substrates 10 and 20 are alternately laminated two or more times. The number of the first and second substrate 10 and 20 which are alternately laminated is not limited.

On the bottom surface of the second substrate 20 disposed at the lowermost position, external connection portions may be provided so as to be electrically connected to the second vias 21 formed in the second substrate 20.

The external connection portions 40 may be solder balls or the like. Between the external connection portions 40 and the second substrate 20, second bonding pads 30 may be additionally formed so as to electrically connect the external connection portions 40 to the second vias 21 within the second substrate 20.

According to this embodiment, the first and second substrate 10 and 20 are formed of silicon and glass, respectively, and are bonded to each other through the anodic bonding, as described above.

As the first and second substrates 10 and 20 are bonded to each other through the anodic bonding, a separate bonding layer for bonding the first and second substrate 10 and 20 does not need to be formed between the first and second substrates 10 and 20. Therefore, it is possible to prevent the circuit patterns 11 from being contaminated by bonding materials.

Further, since there is almost no difference in thermal expansion coefficient between the substrates bonded by the anodic bonding, for example, between silicon and glass, it is possible to prevent warpage caused by a difference in thermal expansion coefficient.

Method of Manufacturing Wafer Level Package

Referring to FIGS. 2 to 4, a method of manufacturing a wafer level package according to an embodiment of the invention will be described.

FIGS. 2 to 4 are process diagrams sequentially showing a method of manufacturing a wafer level package according to an embodiment of the invention.

First, as shown in FIG. 2, a first substrate 10 is prepared. The first substrate 10 has circuit patterns 11 provided on the top surface thereof, first bonding pads 12 provided on the bottom surface thereof, and first vias 13 formed therein, the first via electrically connecting the circuit patterns 11 to the first bonding pads 12.

As described above, the first substrate 10 may be formed of a material containing silicon. Preferably, the first substrate 10 is formed of silicon.

Alternatively, the first substrate 10 may be formed of a material containing alkali metal instead of the material containing silicon. As for the material containing alkali metal, glass or the like may be used.

The circuit patterns 11 and the first bonding pads 12 may be formed of conductive paste or metal.

Next, a second substrate 20 is prepared, which has second vias 21 formed therein, the second vias 21 being disposed at positions corresponding to the first bonding pads 12 of the first substrate 10, respectively.

When the first substrate 10 is formed of a material containing silicon, it is preferable that the second substrate 20 is formed of a material containing alkali metal. When the first substrate 10 is formed of a material containing alkali metal, it is preferable that the second substrate 20 is formed of a material containing silicon.

Then, the second substrate 20 is disposed under the first substrate 10.

At this time, one first substrate 10 and one second substrate 20 may be disposed. However, two or more first substrates 10 and two or more second substrate 20 may be alternatively disposed.

Next, as shown in FIG. 3, the first substrate 10 and the second substrate 20 disposed under the first substrate 10 are bonded to each other through anodic bonding.

In the anodic bonding, when the temperature is increased in a state where silicon and glass are contacted with each other and a voltage is applied in a state where the glass side is set to a cathode and the silicon side is set to an anode, positive ions contained in the glass are forcibly diffused toward the cathode, and a positive ion depletion layer is generated in the vicinity of the bonding interface between the glass and the silicon. In the positive ion depletion layer, negative ions become relatively rich, and negative charges are stored. Further, in the silicon side, while positive charges are stored, a large static attraction force occurs at the interface between the glass and the silicon, so that the glass and the silicon are bonded to each other.

The anodic bonding between the first and second substrates 10 and 20 may be performed under a condition where the temperature is set to less than 200° C. and the voltage is set in the range of 800 to 2000V.

That is, as the anodic boning is performed under the high-voltage condition, a reduction in mobility of the ions is diminished, so that the anodic bonding is smoothly performed in such a low-temperature condition.

At this time, the voltage may be divided into different voltages so as to be applied in a multi-step manner, in order to increase a quantity of charges flowing in the substrates.

For example, the application of the voltage may be divided into first to third steps. In the first step, a voltage of 800V is applied. In the second step, a voltage of 1350V is applied. In the third step, a voltage of 2000V is applied.

According to this embodiment, since the anodic bonding can be performed at a low temperature of less than 200° C, it is possible to prevent the thermal deformation and damage of the substrates caused by high temperature. Further, since the thickness uniformity of the bonded portion is very excellent, it is possible to reduce a thickness variation.

Further, since the chemical resistance and the aging characteristic of the bonded portion through the anodic bonding are excellent, the characteristic of the bonded portion can be prevented from being degraded, which makes it possible to enhance the reliability of the package.

As the first and second substrates 10 and 20 are bonded to each other, the circuit patterns 11 or the first bonding pads 12 of the first substrate 10 can be electrically connected to the second vias 21 of the second substrate 20.

Then, as shown in FIG. 4, external connection portions 40 are formed on the bottom surface of the second substrate 20 which is disposed at the lowermost position among the second substrates 20, the external connection portions 40 being electrically connected to the second vias 21 of the second substrate 20. The external connection portions 40 may be solder balls or the like.

Before the external connection portions 40 are formed, second bonding pads 30 may be formed on the bottom surface of the second substrate 20 so as to be electrically connected to the second vias 21.

According to the present invention, as the substrates are bonded to each other through the anodic bonding, the chemical resistance and aging characteristic of the bonded surface are enhanced, which makes it possible to enhance the reliability of the package. Since the thickness uniformity of the bonded portion is excellent, it is possible to prevent a thickness variation from occurring.

Further, when the substrates are bonded by the anodic bonding, it is possible to prevent warpage caused by a difference in thermal expansion coefficient, because there is almost no difference in thermal expansion coefficient between the substrates.

Furthermore, since a separate adhesive material is not used, it is possible to prevent the circuit patterns from being contaminated.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A wafer level package comprising:
a first substrate that has circuit patterns provided on the top surface thereof and first vias formed therein, the first vias being electrically connected to the circuit patterns; and
a second substrate that is bonded to the bottom surface of the first substrate through anodic bonding and has second vias formed therein.

2. The wafer level package according to claim 1, wherein the first substrate is formed of a material containing silicon or a material containing alkali metal.

3. The wafer level package according to claim 2, wherein the material containing alkali metal is glass.

4. The wafer level package according to claim 2, wherein when the first substrate is formed of a material containing silicon, the second substrate is formed of a material containing alkali metal.

5. The wafer level package according to claim 2, wherein when the first substrate is formed of a material containing alkali metal, the second substrate is formed of a material containing silicon.

6. The wafer level package according to claim 1 further comprising:
bonding pads that are provided between the first and second substrates so as to electrically connect the first vias to the second vias.

7. The wafer level package according to claim 1 further comprising:
external connection portions that are provided on the bottom surface of the second substrate so as to be electrically connected to the second vias.

8. A method of manufacturing a wafer level package, comprising:
providing a first substrate which has circuit patterns provided on the top surface thereof, bonding pads provided on the bottom surface thereof, and first vias formed therein, the first vias electrically connecting the circuit patterns to the bonding pads; and
bonding a second substrate to the bottom surface of the first substrate through anodic bonding, the second substrate having second vias formed therein, the second vias being electrically connected to the bonding pads.

9. The method according to claim 8, wherein the first substrate is formed of a material containing silicon or a material containing alkali metal.

10. The method according to claim 9, wherein the material containing alkali metal is glass.

11. The method according to claim 9, wherein when the first substrate is formed of a material containing silicon, the second substrate is formed of a material containing alkali metal.

12. The method according to claim 9, wherein when the first substrate is formed of a material containing alkali metal, the second substrate is formed of a material containing silicon.

13. The method according to claim 8, wherein the anodic bonding is performed under a condition where the temperature is set to less than 200° C. and a voltage is set in the range of 800 to 2000V.

14. The method according to claim 13, wherein the voltage is divided in different voltages so as to be applied in a multi-step manner.

15. The method according to claim 8 further comprising:
forming external connection portions on the bottom surface of the second substrate, the external connection portions being electrically connected to the second vias, after the bonding of the second substrate.
